(19) United States
(12) Patent Application Publication
(10) Pub. No.: US 2026/0196991 A1
(43) Pub. Date: Jul. 9, 2026

(54) TRUE RANDOM NUMBER GENERATORS INCLUDING RING OSCILLATOR CIRCUITS LEVERAGING FREQUENCY AND PHASE COLLAPSE EVENTS

(71) Applicant: Microsoft Technology Licensing, LLC, Redmond, WA (US)

(72) Inventor: Ting-Yen CHIANG, Palo Alto, CA (US)

(21) Appl. No.: 19/008,958

(22) Filed: Jan. 3, 2025

(51) Int. Cl. H03K 3/84; G06F 7/58; H03K 3/03

(52) U.S. Cl. CPC H03K 3/84; G06F 7/588; H03K 3/0315

(57) ABSTRACT

True random number generators including ring oscillator circuits leveraging frequency and phase collapse events are described. An example ring oscillator circuit (ROC) includes a first oscillating loop comprising a first set of inverters, where the first oscillating loop is to oscillate at a first frequency and phase. The ROC further includes a second oscillating loop comprising a second set of inverters, which differs from the first set of inverters either in terms of a type of inverters or a number of inverters. The second oscillating loop is to oscillate at a second frequency and phase, different from the first frequency and phase. The ROC further includes a third oscillating loop to, as a result of mode switching from a first mode of operation into a second mode of operation, oscillate at a third frequency and phase, different from the first frequency and phase and the second frequency and phase.

### BACKGROUND

A true random number generator (TRNG) is a vital component in many cryptography and security applications. Many security processors include a true random number generator that relies upon the entropy (e.g., randomness) from the environment to generate the random numbers. The random numbers are used for generating keys by a respective processor (e.g., a specific security processor) or by security software executed by a processor. Cryptographic systems included in such processors rely on the unpredictability and the irreproducibility of digital keys that are used for encrypting and/or signing confidential information. The unpredictability and irreproducibility of digital keys depends upon the entropy from the environment (e.g., the variability among dies associated with the processors that are introduced as a result of semiconductor fabrication techniques). Therefore, ensuring robust entropy quality in the true random number generators is crucial. One way to ensure robust entropy is to use certain types of ring oscillators as part of the true random number generators.

True random number generators based on classical ring oscillators have been widely used because of their simplicity and relative ease of modeling. However, such ring oscillators can suffer from a low throughput, a low entropy rate, and a susceptibility to frequency injection type of attacks. Accordingly, there is a need for improvements to the ring oscillators implemented as part of the true random number generators.

### SUMMARY

In one example, the present disclosure relates to a ring oscillator circuit including a first oscillating loop comprising a first set of inverters, where during a first mode of operation of the ring oscillator circuit the first oscillating loop is configured to oscillate at a first frequency and phase. The ring oscillator circuit may further include a second oscillating loop comprising a second set of inverters. The second set of inverters differs from the first set of inverters either in terms of a type of inverters or a number of inverters. During the first mode of operation of the ring oscillator circuit, the second oscillating loop is configured to oscillate at a second frequency and phase, different from the first frequency and phase.

The ring oscillator circuit may further include a third oscillating loop configured to, as a result of mode switching from the first mode of operation into a second mode of operation of the ring oscillator circuit, oscillate at a third frequency and phase, different from both the first frequency and phase and the second frequency and phase.

In another example, the present disclosure relates to a method for operating a ring oscillator circuit comprising: (1) a first oscillating loop comprising a first set of inverters, and (2) a second oscillating loop comprising a second set of inverters, where the second set of inverters differs from the first set of inverters either in terms of a type of inverters or a number of inverters. The method may include during a first mode of operation of the ring oscillator circuit: (1) enabling oscillations in the first oscillating loop at a first frequency and phase, and (2) enabling oscillations in the second oscillating loop at a second frequency and phase, different from the first frequency and phase.

The method may further include during a second mode of the operation of the ring oscillator circuit, enabling a third oscillating loop to oscillate at a third frequency and phase, different from both the first frequency and phase and the second frequency and phase. The method may further include sampling the oscillations in the third oscillating loop to generate bits for random numbers.

In yet another example, the present disclosure relates to a true random number generator circuit. The true random number generator circuit may include a set of short oscillating loops of a ring oscillator circuit, each of which is configured to oscillate at a different frequency and phase.

The true random number generator circuit may further include a long oscillating loop of the ring oscillator circuit configured to oscillate at a third frequency and phase, where the oscillations in the long oscillating loop result from a collision of oscillations in the set of the short oscillating loops. The true random number generator circuit may further include a controller to provide a sampling clock to sample oscillations in the long oscillating loop to generate bits for the true random number generator circuit.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 is a block diagram of an example ring oscillator circuit leveraging frequency and phase collapse events for use with a true random number generator in accordance with one example;

FIG. 2 is a diagram explaining the use of discontinuity-related aspects of the short oscillating loops included within the ring oscillator circuit of FIG. 1;

FIG. 3 shows a view of the ring oscillator circuit of FIG. 1 to further illustrate the discontinuity-related aspects;

FIG. 4 shows waveforms associated with the ring oscillator circuit of FIG. 1 in accordance with one example;

FIG. 5 shows waveforms output from a true random number generator based on the ring oscillator circuit of FIG. 1 in accordance with one example;

FIG. 6 shows an example true random number generator (TRNG) circuit with the ring oscillator circuits described herein; and

FIG. 7 shows waveforms associated with the operation of the true random number generator circuit of FIG. 6 in accordance with one example; and

FIG. 8 shows a flow chart of an example method for operating the ring oscillator circuits described herein.

### DETAILED DESCRIPTION

Examples disclosed in the present disclosure relate to true random number generators including ring oscillator circuits leveraging frequency and phase collapse events. As noted earlier, a true random number generator (TRNG) is a vital component in many cryptography and security applications. Many security processors include a true random number generator that relies upon the entropy (e.g., randomness) from the environment to generate the random numbers. The random numbers are used for generating keys by a respective processor (e.g., a specific security processor) or by security software executed by a processor. Cryptographic systems included in such processors rely on the unpredictability and the irreproducibility of digital keys that are used for encrypting and/or signing confidential information. The unpredictability and irreproducibility of digital keys depends upon the entropy from the environment (e.g., the variability among dies associated with the processors that are introduced as a result of semiconductor fabrication techniques). Therefore, ensuring robust entropy quality in the true random number generators is crucial. One way to ensure robust entropy is to use certain types of ring oscillators as part of the true random number generators.

True random number generators based on classical ring oscillators have been widely used because of their simplicity and relative ease of modeling. However, such ring oscillators can suffer from a low throughput, a low entropy rate, and a susceptibility to frequency injection type of attacks.

Broadly speaking, to address these issues, the examples described herein propose a ring oscillator circuit that introduces a metastable event during the generation of each random bit for the true random number generator. Advantageously, instead of relying on jitter accumulation for random number generation, the true random number generators described herein leverage the metastability phenomenon caused by the multi-mode operation of the ring oscillator circuit. During mode switching, several smaller rings, oscillating at different frequencies and phases, collide into a larger ring and settle into a unified frequency. Such an operation of the ring oscillator circuits results in the frequency and phase collapse. This ensures a stochastic nature of the oscillations, allowing random data to be sampled at a much higher rate with a higher entropy quality.

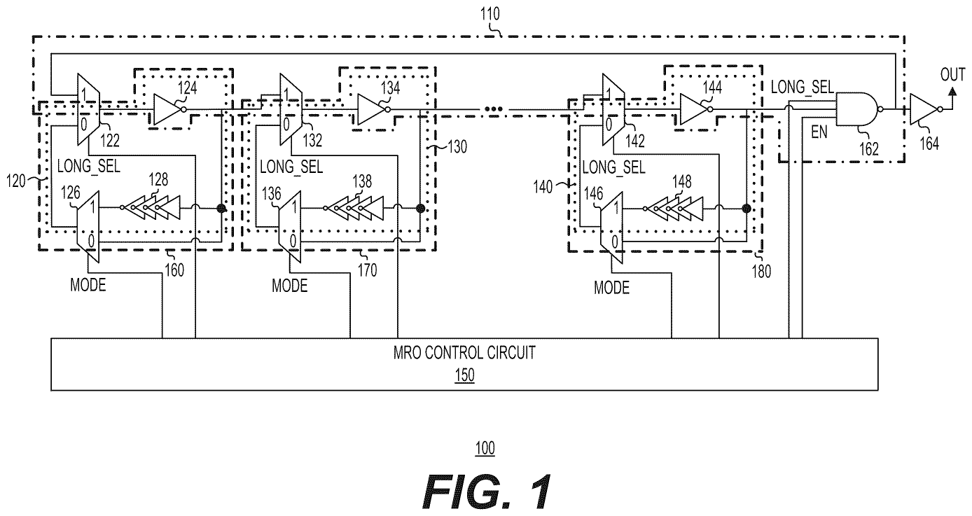

FIG. 1 is a block diagram of an example ring oscillator circuit 100 leveraging frequency and phase collapse events for use with a true random number generator in accordance with one example. Ring oscillator circuit 100 includes a long oscillating loop 110 and multiple short oscillating loops 120, 130, and 140. Each of the short oscillating loops includes several inverter stages. As an example, short oscillating loop 120 includes inverter stages 124 and 128. Each inverter stage can comprise multiple inverters that are coupled in series. The inverters, when connected in a loop fashion, operate as a ring oscillator. Short oscillating loop 130 includes inverter stages 134 and 138. Each inverter stage can comprise multiple inverters that are coupled in series. The inverters, when connected in a loop fashion, operate as a ring oscillator. Short oscillating loop 140 includes inverter stages 144 and 148. Each inverter stage can comprise multiple inverters that are coupled in series. The inverters, when connected in a loop fashion, operate as a ring oscillator.

With continued reference to FIG. 1, a short oscillating loop is formed based on a state of two control signals: the LONG_SEL control signal and the MODE control signal. The LONG_SEL control signal is used to control the operation of multiplexer 122 and the MODE control signal is used to control the operation of multiplexer 126. By selectively coupling the two inputs of each of these multiplexers to a respective output, the ring oscillator circuit 100 can operate in different modes. As an example, depending on the value of the MODE signal, the short oscillating loop can operate in one of two modes. As an example, in one mode (depending upon the state of the MODE signal), short oscillating loop 120 includes inverter stages 124 and 128, while in the other mode, the short oscillating loop 160 includes only inverter stage 124. Other short oscillating loops operate in a similar manner in terms of the state of the MODE signal. Thus, in one mode, short oscillating loop 130 includes inverter stages 134 and 138, while in the other mode, the short oscillating loop 170 includes only inverter stage 134. Similarly, in one mode, short oscillating loop 140 includes inverter stages 144 and 148, while in the other mode, the short oscillating loop 180 includes only inverter stage 144.

Still referring to FIG. 1, in this example, long oscillating loop 110 comprises a ring oscillator having multiple inverter stages (e.g., inverter stages 124, 134, and 144). Each inverter stage can comprise multiple inverters that are coupled in series. The inverters, when connected in a loop fashion, operate as a ring oscillator. Ring oscillator circuit 100 further includes a metastable ring oscillator (MRO) control circuit 150 that is configured to generate several control signals (e.g., including the LONG_SEL control signal and the MODE control signal) for operating the ring oscillator circuit 100. The ring oscillator circuit 100 further includes a NAND gate 162, which is configured to receive the LONG_SEL control signal and an enable (EN) signal. The output of NAND gate 162 is coupled to an inverter stage 164, which provides the output of the ring oscillator circuit 100. Advantageously, instead of relying on jitter accumulation for random number generation, the true random number generators described herein leverage the metastability phenomenon caused by the multi-mode operation of the ring oscillator circuit. During mode switching, several smaller rings, oscillating at different frequencies and phases, collide into a larger ring and settle into a unified frequency. As described herein, the short oscillating loops 120, 130, and 140 correspond to the oscillation loops whose oscillations collide to form the oscillations in the long oscillating loop 110. Such an operation of the oscillating loops associated with the ring oscillator circuit results in the frequency and phase collapse. This ensures a stochastic nature of the oscillations, allowing random data to be sampled at a much higher rate with a higher entropy quality. As described herein, the long oscillating loop 110 corresponds to the oscillating loop whose oscillations are sampled to generate the random bits for a true random number generator. Additional operational aspects of the ring oscillator circuit 100 are explained with the help of waveforms described later. Although FIG. 1 shows ring oscillator circuit 100 as having certain components that are arranged in a certain manner, ring oscillator circuit 100 may include additional or fewer components that are arranged differently.

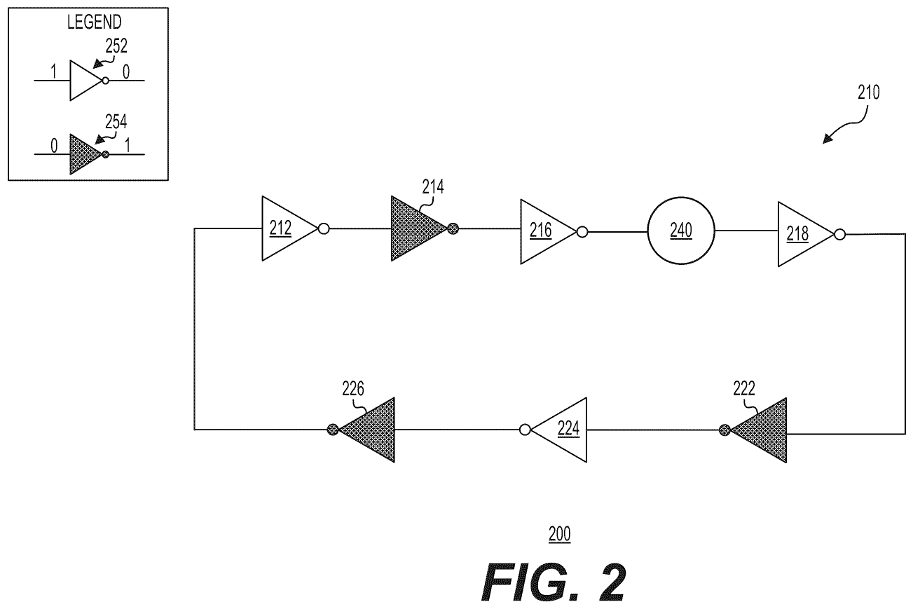

FIG. 2 is a diagram explaining the use of discontinuity-related aspects of the short oscillating loops included within the ring oscillator circuit of FIG. 1. Each of the short oscillating loops (e.g., short oscillating loops 120, 130, and 140 of FIG. 1) includes a ring oscillator with an odd number of inverters to create a discontinuity. FIG. 2 shows an example ring oscillator 210 corresponding to anyone of the short oscillating loops 120, 130, or 140 of FIG. 1. Ring oscillator 210 includes seven inverters (e.g., inverters 212, 214, 216, 218, 222, 224, and 226). At a given time, each of these inverters has either a 0 logical value or a 1 logical value at its input. Similarly, at a given time, each of these inverters has either a 0 logical value or a 1 logical value at its output. As shown in the box labeled as LEGEND, the clear version of the inverter 252 relates to an inverter whose input is logical 1 and output is logical 0. The shaded version of the inverter 254 relates to an inverter whose input is logical 0 and output is logical 1. Ring oscillator 210 is further shown with a discontinuity 240 that is located at an output of inverter 216 and an input of inverter 218. The presence of discontinuity 240, which rotates from one location to another within ring oscillator 210, results in the ring oscillator output signal behaving with an inherent uncertainty. The area of uncertainty within ring oscillator 210 is a function of the characteristics of the inverters used as part of ring oscillator 210. As an example, the characteristics of the inverters may relate to the threshold voltage of the transistors used to form the inverters. Although FIG. 2 shows ring oscillator 210 as having certain components that are arranged in a certain manner, ring oscillator 210 may include additional or fewer components that are arranged differently.

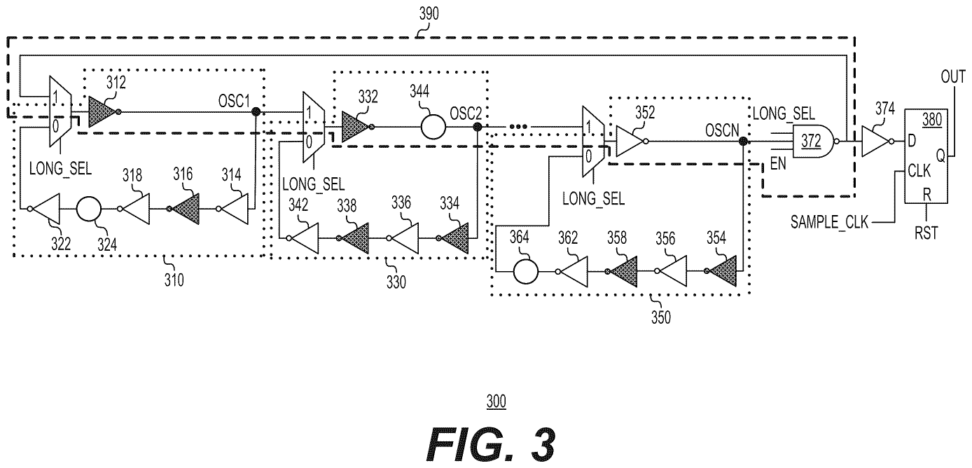

FIG. 3 shows a view 300 of the ring oscillator circuit 100 of FIG. 1 to further illustrate the discontinuity-related aspects. As shown in view 300, the ring oscillator circuit includes three short oscillating loops, including short oscillating loop 310, short oscillating loop 330, and short oscillating loop 350. Each of the short oscillating loops includes an odd number of inverters. As explained earlier with respect to FIG. 2, the area of uncertainty within a ring oscillator is a function of the characteristics of the inverters used as part of the ring oscillator. Each short oscillating loop is implemented using inverters that are of different types because of the different characteristics of the transistors with which they are formed. As an example, short oscillating loop 310 can be formed with inverters that have transistors with a standard threshold voltage (SVT). Short oscillating loop 330 can be formed with inverters that have transistors with a low threshold voltage (LVT). Short oscillating loop 350 can be formed with inverters that have transistors with an ultralow threshold voltage (ULVT). Another short oscillating loop (not shown) could be formed with inverters that have transistors with an extremely low threshold voltage (ELVT). Other characteristics besides the threshold voltage of the devices (e.g., transistors) used to form the inverters can also be varied across the short oscillating loops. As a result of the different characteristics of the inverters used to form the ring oscillators, each of the short oscillating loops oscillates at a different frequency and phase. Instead of forming the short oscillating loops with different types of inverters, each of the short oscillating loops could also be formed with different numbers of inverters.

With continued reference to FIG. 3, short oscillating loop 310 is formed with a ring oscillator that includes five inverters (e.g., inverters 312, 314, 316, 318, and 322). Each of these inverters are of the same type (e.g., inverters that are formed using transistors with a standard threshold voltage). The ring oscillator forming the short oscillating loop 310 is further shown with a discontinuity 324 that is located at an output of inverter 318 and an input of inverter 322. Short oscillating loop 330 is formed with a ring oscillator that also includes five inverters (e.g., inverters 332, 334, 336, 338, and 342). Each of these inverters within short oscillating loop 330 are of the same type (e.g., inverters that are formed using transistors with a low threshold voltage), but different from the inverters used to form the short oscillating loop 310. The ring oscillator forming the short oscillating loop 330 is further shown with a discontinuity 344 that is located at an output of inverter 332 and an input of inverter 334. Short oscillating loop 350 is formed with a ring oscillator that includes five inverters (e.g., inverters 352, 354, 356, 358, and 362). The ring oscillator forming the short oscillating loop 350 is further shown with a discontinuity 364 that is located at an output of inverter 362 and an input of inverter 352. As explained earlier with respect to FIG. 2, at a given time, each of these inverters has either a 0 logical value or a 1 logical value at its input. Similarly, at a given time, each of these inverters has either a 0 logical value or a 1 logical value at its output. Each of the clear versions (similar to clear version 252 of FIG. 2) of the inverters has at its input a logical 1 value and at its output a logical 0 value. Each of the shaded versions (similar to shaded version 254 of FIG. 2) of the inverters has at its input a logical 0 value and at its output a logical 1 value.

As a result of the different characteristics of the inverters used to form the ring oscillators, each of the short oscillating loops oscillates at a different frequency and phase. Thus, short oscillating loop 310 has a ring oscillator, whose oscillations (OSC1) would have a different frequency and phase from the oscillations (OSC2 and OSC3) for short oscillating loops 330 and 350, respectively. Similarly, the frequency and phase of the oscillations (OSC2 and OSC3) would be different in frequency and phase. Accordingly, each of the short oscillating loops has a discontinuity that is rotating within the loop in a different manner. Upon mode switching from the short oscillation loops to the long oscillation loop, the oscillations associated with the short oscillating loops (e.g., short oscillating loops 310, 330, and 350) collide in the long oscillating loop 390, and the three different discontinuities collapse into one discontinuity, which at a given time is different from the discontinuities of each of the short oscillating loops. Thus, several smaller rings, oscillating at different frequencies and phases, collide into a larger ring and settle into a unified frequency. Such an operation of the ring oscillator circuit results in the frequency and phase collapse. This ensures a stochastic nature of the oscillations, allowing random data to be sampled at a much higher rate with a higher entropy quality.

Still referring to FIG. 3, the output of the NAND gate 372 is coupled to an inverter 374, which in turn is coupled to a D-type flip-flop 380. The D-type flip-flop 380 also receives a clock signal (SAMPLE_CLK). In response to receiving the output from the inverter 374, D-type flip-flop 380 generates a binary output comprising random bits corresponding to a random number. Although FIG. 2 shows a view 300 of ring oscillator circuit 100 of FIG. 1 as having certain components that are arranged in a certain manner, ring oscillator circuit 100 may include additional or fewer components that are arranged differently.

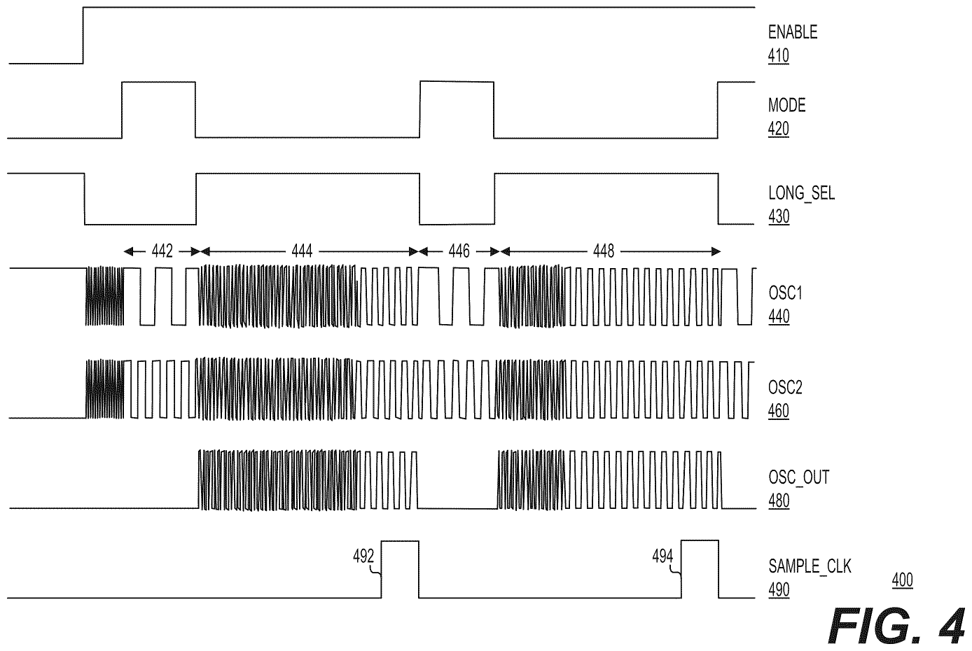

FIG. 4 shows waveforms 400 associated with the ring oscillator circuit of FIG. 1 in accordance with one example. Example waveforms 400 show the behavior of various signals, in relation to time, that are associated with the ring oscillators described herein. ENABLE waveform 410 corresponds to a signal that can be used to enable the ring oscillator circuit. As an example, the ENABLE waveform 410 corresponds to the enable (EN) signal described earlier. As shown in FIG. 4, this signal is asserted to enable the operation cycles for each of the two different modes of operation of the ring oscillator circuit. The MODE waveform 420 corresponds to the signal for short oscillating loops, which is described earlier with respect to FIG. 1 and FIG. 3. Depending on the value of the MODE waveform 420, the short oscillating loop can operate in one of two modes. As an example, in one mode, short oscillating loop 120 of FIG. 1 includes inverter stages 124 and 128, while in the other mode, the short oscillating loop 120 of FIG. 1 includes only inverter stage 124. Other short oscillating loops operate in a similar manner in terms of the state of the MODE waveform 420.

The LONG_SEL waveform 430 corresponds to the signal for the long oscillating loop, which is described earlier with respect to FIG. 1 and FIG. 3. The OSC1 waveform 440 corresponds to the oscillations in one of the short oscillating loops described earlier. As an example, the OSC1 waveform 440 corresponds to the waveform for short oscillating loop 310 of FIG. 3. The OSC2 waveform 460 corresponds to the oscillations in another one of the short oscillating loops described earlier. As an example, the OSC2 waveform 460 corresponds to the waveform for short oscillating loop 330 of FIG. 3. The frequency and phase of the oscillations (OSC1 and OSC2) is different in frequency and phase. Although FIG. 4 shows waveforms for oscillations in only two short oscillating loops, the other short oscillating loops have similar oscillations, but with each oscillating at a different frequency and phase. The OSC_OUT waveform 480 corresponds to the output oscillations of the ring oscillator circuits described earlier with respect to FIGS. 1-3. As an example, the OSC_OUT waveform 480 corresponds to the waveform output at the terminal labeled as OUT in FIG. 1 and FIG. 3.

With continued reference to FIG. 4, portions 442 and 446 of the oscillations correspond to the oscillations in the short oscillating loops. Portions 444 and 448 of the oscillations correspond to the oscillations in the long oscillating loop. As explained earlier with respect to FIGS. 2 and 3, each of the short oscillating loops has a discontinuity that is rotating within the loop in a different manner. Upon the collapse of the short oscillating loops (e.g., the oscillations represented by OSC1 waveform 440 and OSC2 waveform 460) into a long oscillating loop (e.g., the oscillations represented by OSC_OUT waveform 480), the different discontinuities collapse into one discontinuity, which at a given time is different from the discontinuities of each of the short oscillating loops. A metastable ring oscillator control circuit (e.g., MRO control circuit 150 of FIG. 1) is configured to keep operating the ring oscillator circuit in these alternating modes (the short loops vs. the long loop) until the ring oscillator circuit is turned off or otherwise reset. Thus, several smaller rings, oscillating at different frequencies and phases, collide into a larger ring and settle into a unified frequency. Such an operation of the ring oscillator circuits results in the frequency and phase collapse. This ensures a stochastic nature of the oscillations, allowing random data to be sampled at a much higher rate with a higher entropy quality.

SAMPLE_CLK waveform 490 corresponds to the sampling clock used to sample an output of the ring oscillator circuit. In this example, a rising edge 492 of the SAMPLE_CLK waveform 490 is used to generate a random bit from the oscillations (OSC_OUT waveform 480) associated with the long oscillating loop. In addition, another rising edge 494 of the SAMPLE_CLK waveform 490 is used to generate a subsequent random bit from the oscillations associated with the long oscillating loop. Falling edges can also be used for sampling. In addition, as needed, the specific edge of the clock (e.g., SAMPLE_CLK waveform 490) that is used for sampling can be moved by introducing random delays.

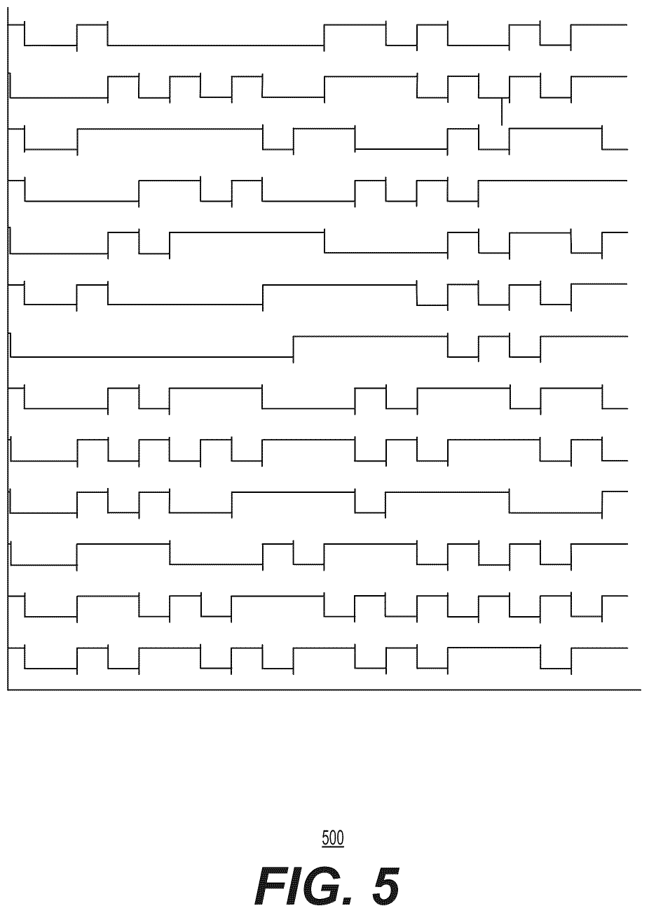

FIG. 5 shows waveforms 500 output from a true random number generator based on the ring oscillator circuit of FIG. 1 in accordance with one example. As described earlier, the ring oscillator circuit included within the true random number generator is operated in alternating modes (the short loops vs. the long loop) until the ring oscillator circuit is turned off or otherwise reset. Thus, several smaller rings, oscillating at different frequencies and phases, collide into a larger ring and settle into a unified frequency. Such an operation of the ring oscillator circuits results in the frequency and phase collapse. This ensures a stochastic nature of the oscillations, allowing random data to be sampled at a much higher rate with a higher entropy quality. Waveforms 500 show output random number sequences that are generated by the true random number generator. From the waveforms 500, it is evident that the output of the true random number generator is not deterministic; instead, each of the sequences is different.

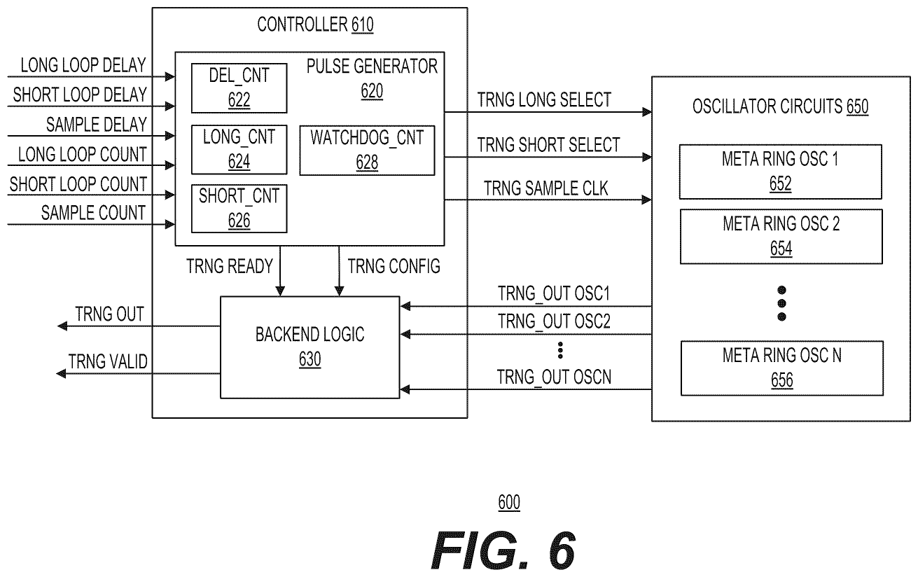

FIG. 6 shows an example true random number generator (TRNG) circuit 600 with the ring oscillator circuits described herein. TRNG circuit 600 includes a controller 610 and oscillator circuits 650. Controller 610 is programmable and configurable to allow for flexibility in terms of the operational aspects of TRNG CIRCUIT 600. In this example, controller 610 includes a pulse generator 620 and backend logic 630. Table 1 below lists an example set of signals for configuring certain aspects of the true random number generator (TRNG) signals. Pulse generator includes storage (e.g., DEL_CNT 622, LONG_CNT 624, and SHORT_CNT 626) for storing the values for the TRNG configuration signals listed in Table 1 below.

TABLE 1

| TRNG | |
|---|---|
| CONFIGURATION | DESCRIPTION OF THE |
| SIGNALS | TRNG SIGNALS |
| LONG LOOP | Programmable delay for the start time for the |
| DELAY | oscillations in the long oscillation loop |
| SHORT LOOP | Programmable delay for the start time for the |
| DELAY | oscillations in the short oscillation loops |
| SAMPLE DELAY | Programmable delay for the sampling clock |
| | (e.g., SAMPLE_CLK) |
| LONG LOOP | Duration of the long loop oscillations phase |
| COUNT | |
| SHORT LOOP | Duration of the short loop oscillations phase |
| COUNT | |
| SAMPLE COUNT | Sampling clock frequency |

With continued reference to FIG. 6, pulse generator 620 further includes a watchdog (e.g., WATCHDOG_CNT 628) to ensure the functionality of these counters described above. Controller 610 also provides certain signals to backend logic 630. In this example, controller 610 provides a TRNG READY and a TRNG CONFIG signal to backend logic 630, which can be used to perform post processing. As an example, by receiving data from the oscillator circuits 650 and the controller 610, backend logic 630 can perform decorrelation and help improve the entropy of the bitstream (TRNG OUT) generated by true random number generator circuit 600. In this example, the oscillator circuits 650 need three control signals to function, which are generated by controller 610. Oscillator circuits 650 can include any number of ring oscillator circuits (e.g., META RING OSC 1 652, META RING OSC 2 654, and META RING OSC N 656) described earlier with respect to FIGS. 1-5. An example set of signals received and generated by oscillator circuits 650 is shown in Table 2 below.

TABLE 2

| TRNG SIGNALS | DESCRIPTION OF THE TRNG SIGNALS |
|---|---|
| TRNG LONG | Long oscillation loop selection signal |
| SELECT | |
| TRNG SHORT | Short oscillation loop selection signal |
| SELECT | |
| TRNG SAMPLE | Sampling clock |
| CLK | |
| TRNG_OUT | Output oscillations of the ring oscillator |
| OSC1 | META RING OSC1 |
| TRNG OUT | Output oscillations of the ring oscillator |
| OSC2 | META RING OSC2 |
| TRNG_OUT | Output oscillations of the ring oscillator |
| OSCN | META RING OSCN |
| TRNG OUT | Output random bits from the true random |
| | number generator |

Although FIG. 6 shows true random number generator circuit 600 as having certain components that are arranged in a certain manner, true random number generator circuit 600 may include additional or fewer components that are arranged differently.

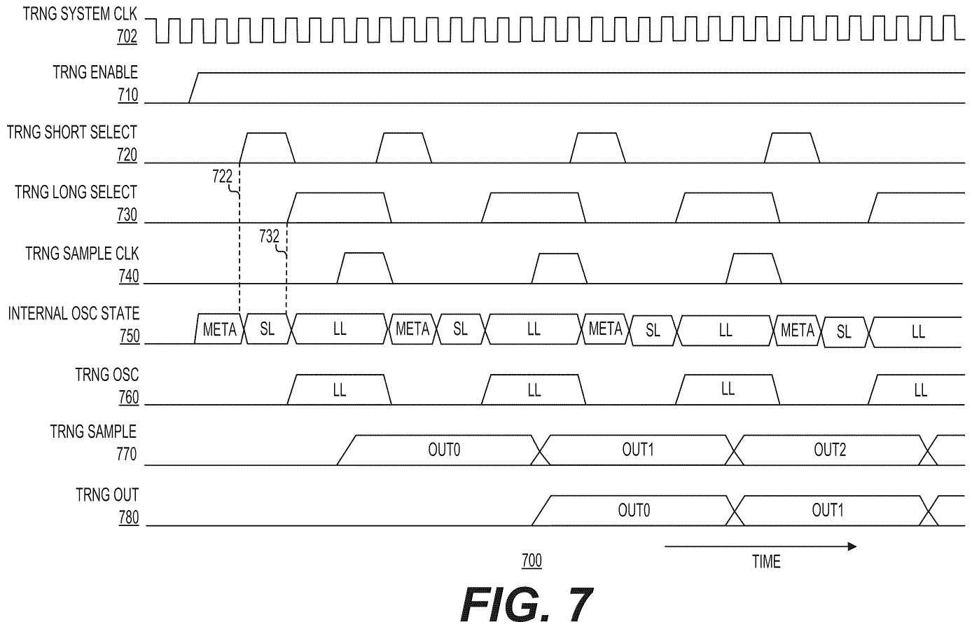

FIG. 7 shows waveforms 700 associated with operation of the true random number generator (TRNG) circuit 600 of FIG. 6 in accordance with one example. Example waveforms 700 show the behavior of various signals, in relation to time, that are associated with the true random number generator (TRNG) circuit 600 of FIG. 6. TRNG SYSTEM CLK waveform 702 corresponds to the system clock signal. TRNG ENABLE waveform 710 corresponds to a signal that can be used to enable the true random number generator. As an example, the TRNG ENABLE waveform 710 enables the remaining operations of the true random number generator, including enabling the ring oscillator circuits. As shown in FIG. 7, this signal is asserted to enable the operation cycles for each of the three different modes of operation of the true random number generator.

The TRNG SHORT SELECT waveform 720 corresponds to the signal for short oscillating loops, which is described earlier with respect to FIG. 6. The TRNG LONG SELECT waveform 720 corresponds to the signal for short oscillating loops, which is described earlier with respect to FIG. 6.

With continued reference to FIG. 7, the TRNG SAMPLE CLK wave form 740 corresponds to the sampling clock (TRNG SAMPLE CLK), which is described earlier with respect to FIG. 6. In this example, a rising edge of the TRNG SAMPLE CLK waveform 740 is used to sample the oscillations associated with the long oscillating loop. Falling edges can also be used for sampling. The INTERNAL OSC STATE waveform 750 corresponds to the internal oscillations in a ring oscillator circuit associated with the true random number generator. In this case, the internal oscillations can be in one of three states—meta, short oscillator loop (SL) or long oscillator loop (LL). As explained earlier with respect to FIG. 1, depending on the value of the MODE signal of FIG. 1, the short oscillating loop can operate in one of two modes. As an example, in one mode, short oscillating loop 120 of FIG. 1 includes inverter stages 124 and 128, while in the other mode, the short oscillating loop 120 of FIG. 1 includes only inverter stage 124. Other short oscillating loops operate in a similar manner in terms of the state of the MODE signal. The internal oscillations of the ring oscillator are in the meta state when the short oscillating loop 120 of FIG. 1 includes inverter stage 124 only, and does not include inverter stage 128. The internal oscillations of the ring oscillator are in the short oscillator loop (SL) state when the short oscillating loop 120 of FIG. 1 includes both of the inverter stage 124 and the inverter stage 128. The long oscillator loop (LL) state of the INTERNAL OSC STATE waveform 750 corresponds to the long oscillator loop's oscillations.

Still referring to FIG. 7, TRNG OSC waveform 760 corresponds to the long oscillator loop's oscillations. The TRNG SAMPLE waveform 770 corresponds to the sampled signals that are generated by sampling the TRNG OSC waveform 760. Finally, the TRNG OUT waveform 780 corresponds to the output of the true random number generator, which is referred to in FIG. 6. Although FIG. 7 shows waveforms 700 having certain timing relationships and duration, the control signals associated with the true random generator circuit 600 of FIG. 6 could be programmed to vary the timing relationships and the duration of the signals whose waveforms are shown in FIG. 7.

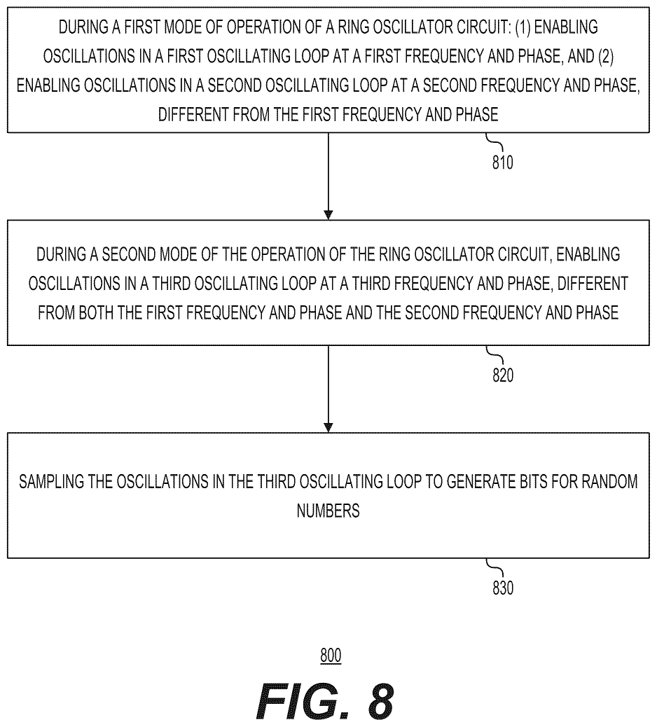

FIG. 8 shows a flow chart of an example method for operating the ring oscillator circuits described herein. In one example, the ring oscillator circuit corresponds to ring oscillator circuit 100 of FIG. 1, further described with respect to FIGS. 2-4. As described earlier, the ring oscillator circuit includes several short oscillating loops (e.g., short oscillating loops 120, 130, and 140 of FIG. 1) and one long oscillating loop (e.g., long oscillating loop 110). Step 810 includes during a first mode of operation of the ring oscillator circuit: (1) enabling oscillations in the first oscillating loop at a first frequency and phase, and (2) enabling oscillations in the second oscillating loop at a second frequency and phase, different from the first frequency and phase. As described earlier, a ring oscillator control circuit (e.g., MRO control circuit 150 of FIG. 1) can be used to enable oscillations in the short oscillating loops. The waveforms shown in FIG. 4 and FIG. 7 further illustrate the timing and the duration associated with the oscillations in the short oscillating loops. With respect to FIG. 4, as an example, the first mode of operation corresponds to oscillations shown in portion 442 and portion 446 of OSC1 waveform 440 for the oscillations in one of the short oscillating loops. Similar oscillations, but with a different frequency and phase, occur in another one of the short oscillating loops included within the ring oscillator circuit.

Step 820 includes during a second mode of the operation of the ring oscillator circuit, enabling a third oscillating loop to oscillate at a third frequency and phase, different from both the first frequency and phase and the second frequency and phase. As described earlier, the ring oscillator circuit includes several short oscillating loops (e.g., short oscillating loops 120, 130, and 140 of FIG. 1) and one long oscillating loop (e.g., long oscillating loop 110). Moreover, as described earlier, a ring oscillator control circuit (e.g., MRO control circuit 150 of FIG. 1) can be used to enable oscillations in the long oscillating loop. The waveforms shown in FIG. 4 and FIG. 7 further illustrate the timing and the duration associated with the oscillations in the short oscillating loops. As an example, portions 444 and 448 of FIG. 4 of the oscillations correspond to the oscillations in the long oscillating loop.

As explained earlier with respect to FIGS. 2 and 3, each of the short oscillating loops has a discontinuity that is rotating within the loop in a different manner. Upon the collapse of the short oscillating loops (e.g., the oscillations represented by OSC1 waveform 440 of FIG. 4 and OSC2 waveform 460 of FIG. 4) into a long oscillating loop (e.g., the oscillations represented by OSC_OUT waveform 480 of FIG. 4), the different discontinuities collapse into one discontinuity, which at a given time is different from the discontinuities of each of the short oscillating loops. A metastable ring oscillator control circuit (e.g., MRO control circuit 150 of FIG. 1) is configured to keep operating the ring oscillator circuit in these alternating modes (the short loops vs. the long loop) until the ring oscillator circuit is turned off or otherwise reset. Thus, several smaller rings, oscillating at different frequencies and phases, collide into a larger ring and settle into a unified frequency. Such an operation of the ring oscillator circuits results in the frequency and phase collapse. Advantageously, this ensures a stochastic nature of the oscillations, allowing random data to be sampled at a much higher rate with a higher entropy quality.

Step 830 includes sampling the oscillations in the third oscillating loop to generate bits for random numbers. The oscillations in the third oscillating loop result from a collision of oscillations of the first oscillating loop and the second oscillating loop. The collision of the oscillations of the first oscillating loop and the second oscillating loop results in a frequency and phase collapse event, ensuring a stochastic nature of the oscillations in the third oscillating loop. As explained earlier, the SAMPLE_CLK waveform 490 of FIG. 4 corresponds to the sampling clock used to sample an output of the ring oscillator circuit. Either the rising edges or the falling edges can be used for sampling the oscillations in the third oscillating loop (e.g., long oscillating loop 110 of FIG. 1).

In conclusion, the present disclosure relates to a ring oscillator circuit including a first oscillating loop comprising a first set of inverters, where during a first mode of operation of the ring oscillator circuit the first oscillating loop is configured to oscillate at a first frequency and phase. The ring oscillator circuit may further include a second oscillating loop comprising a second set of inverters. The second set of inverters differs from the first set of inverters either in terms of a type of inverters or a number of inverters. During the first mode of operation of the ring oscillator circuit, the second oscillating loop is configured to oscillate at a second frequency and phase, different from the first frequency and phase.

The ring oscillator circuit may further include a third oscillating loop configured to, as a result of mode switching from the first mode of operation into a second mode of operation of the ring oscillator circuit, oscillate at a third frequency and phase, different from both the first frequency and phase and the second frequency and phase. The oscillations in the third oscillating loop result from a collision of oscillations in the first oscillating loop and oscillations in the second oscillating loop.

In addition, the collision of the oscillations results in a frequency and phase collapse event, ensuring a stochastic nature of the oscillations in the third oscillating loop. The stochastic nature of the oscillations in the third oscillating loop allows for a generation of a respective random bit by a true random number generator incorporating the ring oscillator circuit.

The ring oscillator circuit may further include a ring oscillator control circuit to generate a control signal to: (1) during the first mode of operation of the ring oscillator circuit, enable oscillations in both the first oscillating loop and the second oscillating loop for a first duration, and (2) during the second mode of operation of the ring oscillator circuit, enable oscillations in the third oscillating loop for a second duration, different from the first duration. The difference in the type of inverters between the first set of inverters and the second set of inverters may relate to a difference in a threshold voltage of transistors used to form respective sets of inverters.

In another example, the present disclosure relates to a method for operating a ring oscillator circuit comprising: (1) a first oscillating loop comprising a first set of inverters, and (2) a second oscillating loop comprising a second set of inverters, where the second set of inverters differs from the first set of inverters either in terms of a type of inverters or a number of inverters. The method may include during a first mode of operation of the ring oscillator circuit: (1) enabling oscillations in the first oscillating loop at a first frequency and phase, and (2) enabling oscillations in the second oscillating loop at a second frequency and phase, different from the first frequency and phase.

The method may further include during a second mode of the operation of the ring oscillator circuit, enabling a third oscillating loop to oscillate at a third frequency and phase, different from both the first frequency and phase and the second frequency and phase. The method may further include sampling the oscillations in the third oscillating loop to generate bits for random numbers. The oscillations in the third oscillating loop result from a collision of oscillations of the first oscillating loop and oscillations in the second oscillating loop.

The collision of the oscillations results in a frequency and phase collapse event, ensuring a stochastic nature of the oscillations in the third oscillating loop. The stochastic nature of the oscillations in the third oscillating loop allows for a generation of a respective random bit by a true random number generator incorporating the ring oscillator circuit.

The method may further include, during the first mode of operation of the ring oscillator circuit, using a ring oscillator control circuit to enable oscillations in both the first oscillating loop and the second oscillating loop for a first duration. The method may further include, during the second mode of operation of the ring oscillator circuit, using the ring oscillator control circuit to enable oscillations in the third oscillating loop for a second duration, different from the first duration. The difference in the type of inverters between the first set of inverters and the second set of inverters may relate to a difference in a threshold voltage of transistors used to form respective sets of inverters.

In yet another example, the present disclosure relates to a true random number generator circuit. The true random number generator circuit may include a set of short oscillating loops of a ring oscillator circuit, each of which is configured to oscillate at a different frequency and phase.

The true random number generator circuit may further include a long oscillating loop of the ring oscillator circuit configured to oscillate at a third frequency and phase, where the oscillations in the long oscillating loop result from a collision of oscillations in the set of the short oscillating loops. The true random number generator circuit may further include a controller to provide a sampling clock to sample oscillations in the long oscillating loop to generate bits for the true random number generator circuit.

As part of the true random number generator circuit, the inverters included within each of the set of short oscillating loops differ from one short oscillating loop to another short oscillating loop either in terms of a type of inverters or a number of inverters. The difference in the type of inverters may relate to a difference in a threshold voltage of transistors used to form respective inverters.

The true random number generator circuit may further include a ring oscillator control circuit to generate a control signal to: (1) during a first mode of operation of the ring oscillator circuit, enable oscillations in each of the set of short oscillating loops for a first duration, and (2) during the second mode of operation of the ring oscillator circuit, enable oscillations in the long oscillating loop for a second duration, different from the first duration. The controller may further be configured to specify a programmable measure of each of the first duration and the second duration.

As part of the true random number generator circuit, the collision of the oscillations in the set of short oscillating loops results in a frequency and phase collapse event, ensuring a stochastic nature of the oscillations in the long oscillating loop. The stochastic nature of the oscillations in the long oscillating loop allows for generation of bits for the true random number generator circuit with a higher entropy quality than realizable based on jitter accumulation alone.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), or Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

The functionality associated with some examples described in this disclosure can also include instructions stored in a non-transitory media. The term “non-transitory media” as used herein refers to any media storing data and/or instructions that cause a machine to operate in a specific manner. Exemplary non-transitory media include non-volatile media and/or volatile media. Non-volatile media include, for example, a hard disk, a solid state drive, a magnetic disk or tape, an optical disk or tape, a flash memory, an EPROM, NVRAM, PRAM, or other such media, or networked versions of such media. Volatile media include, for example, dynamic memory, such as, DRAM, SRAM, a cache, or other such media. Non-transitory media is distinct from, but can be used in conjunction with transmission media. Transmission media is used for transferring data and/or instruction to or from a machine. Exemplary transmission media, include coaxial cables, fiber-optic cables, copper wires, and wireless media, such as radio waves.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A ring oscillator circuit comprising:
a first oscillating loop comprising a first set of inverters, wherein during a first mode of operation of the ring oscillator circuit the first oscillating loop is configured to oscillate at a first frequency and phase;
a second oscillating loop comprising a second set of inverters, wherein the second set of inverters differs from the first set of inverters either in terms of a type of inverters or a number of inverters, and wherein during the first mode of operation of the ring oscillator circuit, the second oscillating loop is configured to oscillate at a second frequency and phase, different from the first frequency and phase; and
a third oscillating loop configured to, as a result of mode switching from the first mode of operation into a second mode of operation of the ring oscillator circuit, oscillate at a third frequency and phase, different from both the first frequency and phase and the second frequency and phase.

2. The ring oscillator circuit of claim 1, wherein the oscillations in the third oscillating loop result from a collision of oscillations in the first oscillating loop and oscillations in the second oscillating loop.

3. The ring oscillator circuit of claim 2, wherein the collision of the oscillations results in a frequency and phase collapse event, ensuring a stochastic nature of the oscillations in the third oscillating loop.

4. The ring oscillator circuit of claim 3, wherein the stochastic nature of the oscillations in the third oscillating loop allows for a generation of a respective random bit by a true random number generator incorporating the ring oscillator circuit.

5. The ring oscillator circuit of claim 1, further comprising a ring oscillator control circuit to generate a control signal to: (1) during the first mode of operation of the ring oscillator circuit, enable oscillations in both the first oscillating loop and the second oscillating loop for a first duration, and (2) during the second mode of operation of the ring oscillator circuit, enable oscillations in the third oscillating loop for a second duration, different from the first duration.

6. The ring oscillator circuit of claim 1, wherein the difference in the type of inverters between the first set of inverters and the second set of inverters relates to a difference in a threshold voltage of transistors used to form respective sets of inverters.

7. A method for operating a ring oscillator circuit comprising: (1) a first oscillating loop comprising a first set of inverters, and (2) a second oscillating loop comprising a second set of inverters, wherein the second set of inverters differs from the first set of inverters either in terms of a type of inverters or a number of inverters, the method comprising:
during a first mode of operation of the ring oscillator circuit: (1) enabling oscillations in the first oscillating loop at a first frequency and phase, and (2) enabling oscillations in the second oscillating loop at a second frequency and phase, different from the first frequency and phase;
during a second mode of the operation of the ring oscillator circuit, enabling a third oscillating loop to oscillate at a third frequency and phase, different from both the first frequency and phase and the second frequency and phase; and
sampling the oscillations in the third oscillating loop to generate bits for random numbers.

8. The method of claim 7, wherein the oscillations in the third oscillating loop result from a collision of oscillations of the first oscillating loop and oscillations in the second oscillating loop.

9. The method of claim 8, wherein the collision of the oscillations results in a frequency and phase collapse event, ensuring a stochastic nature of the oscillations in the third oscillating loop.

10. The method of claim 9, wherein the stochastic nature of the oscillations in the third oscillating loop allows for a generation of a respective random bit by a true random number generator incorporating the ring oscillator circuit.

11. The method of claim 7, further comprising, during the first mode of operation of the ring oscillator circuit, using a ring oscillator control circuit to enable oscillations in both the first oscillating loop and the second oscillating loop for a first duration.

12. The method of claim 9, further comprising, during the second mode of operation of the ring oscillator circuit, using the ring oscillator control circuit to enable oscillations in the third oscillating loop for a second duration, different from the first duration.

13. The method of claim 7, wherein the difference in the type of inverters between the first set of inverters and the second set of inverters relates to a difference in a threshold voltage of transistors used to form respective sets of inverters.

14. A true random number generator circuit comprising:
a set of short oscillating loops of a ring oscillator circuit, each of which is configured to oscillate at a different frequency and phase;
a long oscillating loop of the ring oscillator circuit configured to oscillate at a third frequency and phase, wherein the oscillations in the long oscillating loop result from a collision of oscillations in the set of the short oscillating loops; and
a controller to provide a sampling clock to sample oscillations in the long oscillating loop to generate bits for the true random number generator circuit.

15. The true random number generator circuit of claim 14, wherein inverters included within each of the set of short oscillating loops differ from one short oscillating loop to another short oscillating loop either in terms of a type of inverters or a number of inverters.

16. The true random number generator circuit of claim 15, wherein the difference in the type of inverters relates to a difference in a threshold voltage of transistors used to form respective inverters.

17. The true random number generator circuit of claim 14, further comprising a ring oscillator control circuit to generate a control signal to: (1) during a first mode of operation of the ring oscillator circuit, enable oscillations in each of the set of short oscillating loops for a first duration, and (2) during the second mode of operation of the ring oscillator circuit, enable oscillations in the long oscillating loop for a second duration, different from the first duration.

18. The true random number generator circuit of 17, wherein the controller is further configured to specify a programmable measure of each of the first duration and the second duration.

19. The true random number generator circuit of claim 14, wherein the collision of the oscillations in the set of short oscillating loops results in a frequency and phase collapse event, ensuring a stochastic nature of the oscillations in the long oscillating loop.

20. The true random number generator circuit of claim 19, wherein the stochastic nature of the oscillations in the long oscillating loop allows for generation of bits for the true random number generator circuit with a higher entropy quality than realizable based on jitter accumulation alone.
